(19) United States
(12) Patent Application Publication
(10) Pub. No.: US 2026/0271370 A1
(43) Pub. Date: Sep. 10, 2026

(54) SEMICONDUCTOR DEVICE

(71) Applicant: Kioxia Corporation, Tokyo (JP)

(72) Inventor: Tomoya WADA, Yokkaichi (JP)

(73) Assignee: Kioxia Corporation, Tokyo (JP)

(21) Appl. No.: 19/328,241

(22) Filed: Sep. 15, 2025

(30) Foreign Application Priority Data
Mar. 5, 2025 (JP) 2025-034576

(51) Int. Cl. H10D 64/62; H01L 25/18; H10B 80/00; H10D 30/01; H10D 62/13; H10D 64/23; H10D 64/27; H10D 64/66; H10D 80/30; H10D 84/83

(52) U.S. Cl. CPC H10D 64/62; H10D 30/0212; H10D 62/151; H10D 64/258; H10D 64/518; H10D 64/519; H10D 64/675; H10D 84/83; H10B 80/00; H10D 80/30; H10W 90/00

(57) ABSTRACT

A semiconductor device includes first and second diffusion layer regions spaced apart on a semiconductor substrate. A gate insulating film is on the semiconductor substrate, and a part of the gate insulating film is in a region between the first and second diffusion layer regions. A gate electrode is on an opposite side of the gate insulating film from the semiconductor substrate. A first base conductive region is on an opposite side of the first diffusion layer region from the semiconductor substrate, and a first connection conductive region is connected to the first base conductive region. A second base conductive region is on an opposite side of the second diffusion layer region from the semiconductor substrate, and a second connection conductive region is connected thereto. A height of the first or second base conductive region is equal to or less than a height of the gate electrode.

### CROSS-REFERENCE TO RELATED APPLICATION

This application is based upon and claims the benefit of priority from Japanese Patent Application No. 2025-034576, filed Mar. 5, 2025, the entire contents of which are incorporated herein by reference.

### FIELD

Embodiments described herein relate generally to a semiconductor device.

### BACKGROUND

A semiconductor device including a semiconductor substrate and a plurality of transistors provided on the semiconductor substrate is known.

### BRIEF DESCRIPTION OF THE DRAWINGS

FIG. 1 is a cross-sectional view illustrating a configuration example of a semiconductor device of a first embodiment.

FIG. 2 is a partial cross-sectional view illustrating a transistor provided on the semiconductor device.

FIG. 3 is a plan view illustrating an example of the planar layout of the transistor.

FIG. 4 is a plan view illustrating the planar layout according to a second embodiment of the transistor.

FIG. 5 is a partial cross-sectional view illustrating a problem of a transistor of a comparative example.

FIG. 6 is a plan view illustrating the problem in the transistor of the comparative example.

FIG. 7A is an explanatory diagram illustrating a step of forming a transistor on a semiconductor substrate.

FIG. 7B is an explanatory diagram illustrating a step of forming the transistor on the semiconductor substrate.

FIG. 7C is an explanatory diagram illustrating a step of forming the transistor on the semiconductor substrate.

FIG. 7D is an explanatory diagram illustrating a step of forming the transistor on the semiconductor substrate.

FIG. 8A is an explanatory diagram illustrating a step of forming the transistor on the semiconductor substrate.

FIG. 8B is an explanatory diagram illustrating a step of forming the transistor on the semiconductor substrate.

FIG. 8C is an explanatory diagram illustrating a step of forming the transistor on the semiconductor substrate.

FIG. 8D is an explanatory diagram illustrating a step of forming the transistor on the semiconductor substrate.

FIG. 8E is an explanatory diagram illustrating a step of forming the transistor on the semiconductor substrate.

FIG. 8F is an explanatory diagram illustrating a step of forming the transistor on the semiconductor substrate.

FIG. 8G is an explanatory diagram illustrating a step of forming the transistor on the semiconductor substrate.

FIG. 9 is a cross-sectional view illustrating a configuration example of a transistor provided on a semiconductor device of a third embodiment.

FIG. 10 is an explanatory diagram illustrating a step of manufacturing a transistor having the planar layout illustrated in FIG. 4.

FIG. 11 is an explanatory diagram illustrating an example of the cross-sectional structure of the transistor having the planar layout illustrated in FIG. 4.

### DETAILED DESCRIPTION

An object of one embodiment is to provide a semiconductor device capable of reducing parasitic capacitance.

In general, according to one embodiment, a semiconductor device of an embodiment includes a semiconductor substrate. The semiconductor device includes a first diffusion layer region and a second diffusion layer region provided on the semiconductor substrate to be spaced apart from each other in a surface direction of the semiconductor substrate. The semiconductor device includes a gate insulating film provided on the semiconductor substrate, at least a part of the gate insulating film being located in an area between the first diffusion layer region and the second diffusion layer region. The semiconductor device includes a gate electrode located on an opposite side of the gate insulating film from the semiconductor substrate. The semiconductor device includes a first base conductive region provided on an opposite side of the first diffusion layer region from the semiconductor substrate, the first base conductive region extending in a surface direction of the semiconductor substrate. The semiconductor device incudes a first connection conductive region provided to be connected to the first base conductive region. The semiconductor device includes a second base conductive region provided on an opposite side of the second diffusion layer region from the semiconductor substrate, the second base conductive region extending in a surface direction of the semiconductor substrate. The semiconductor device includes a second connection conductive region provided to be connected to the second base conductive region. A height of at least one of the first base conductive region and the second base conductive region is equivalent to a height of the gate electrode, or lower than the height of the gate electrode.

Hereinafter, a semiconductor device of a first embodiment will be described with reference to the drawings. In the following description, the same numerals are given to configurations having the same or similar functions. In addition, overlapping descriptions of such configurations may be omitted. “Parallel”, “orthogonal”, or “the same” may include cases of “substantially parallel”, “substantially orthogonal”, or “substantially the same”, respectively. “Connection” is not limited to mechanical connection, and may include electric connection. That is, “connection” is not limited to cases in which a plurality of elements are directly connected, and may include cases in which a plurality of elements are connected via another element. “Face” means that two members overlap when viewed in a certain direction, and may also include cases in which another member exists between the two members.

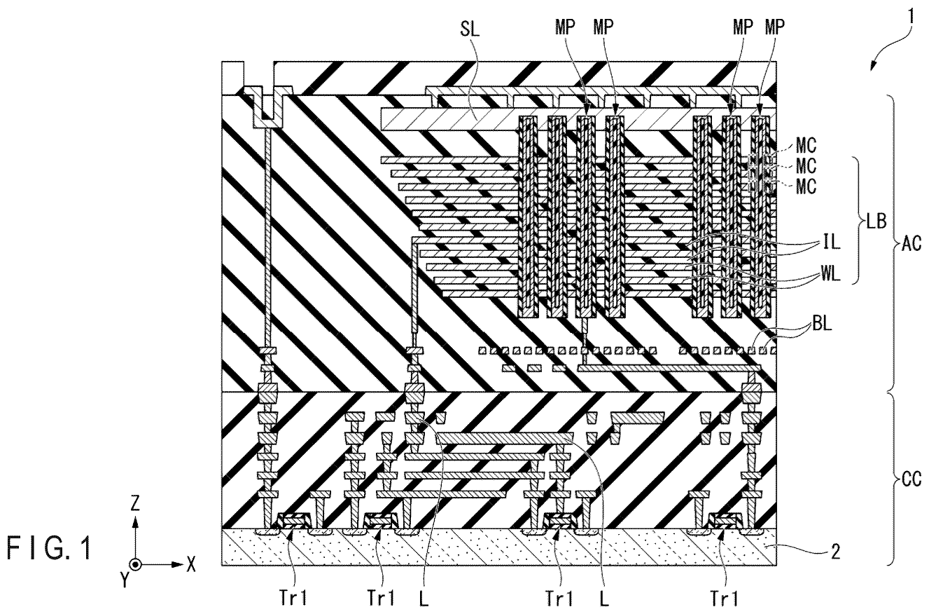

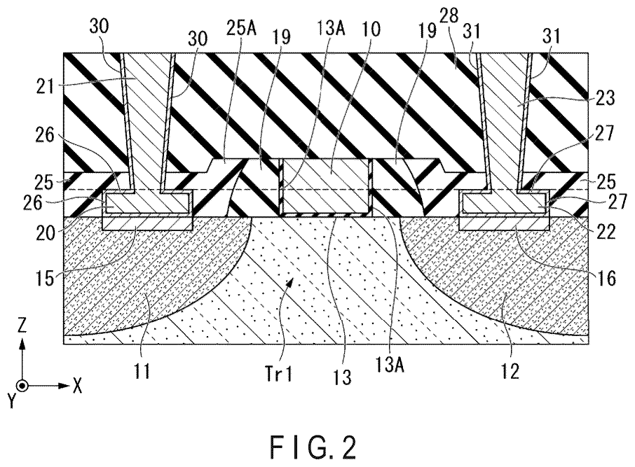

First, an X direction, a Y direction, and a Z direction are defined. The X direction and the Y direction are directions along a surface of a semiconductor substrate 2, which will be described later (refer to FIG. 1). The X direction is a direction from a first diffusion layer region (source region) 11 toward a second diffusion layer region (drain region) 12 in a first transistor 5, which will be described later (refer to FIG. 2). The Y direction is a direction that intersects (for example, that is orthogonal to) the X direction. The Z direction is a direction that intersects (for example, that is orthogonal) to the X direction and the Y direction. The Z direction is a thickness direction of the semiconductor substrate 2. In the following description, the side of the semiconductor substrate 2 on which transistors Tr1 are located may be referred to as “above”, and the opposite side may be referred to as “below.” However, these expressions are for convenience, and do not specify the gravity direction.

### First Embodiment

### 1. Configuration Example of Semiconductor Device

FIG. 1 is a cross-sectional view illustrating a configuration example of a semiconductor device 1 of the first embodiment. The semiconductor device 1 is, for example, a semiconductor memory device such as a NAND flash memory. The semiconductor device 1 includes, for example, an array chip AC and a circuit chip CC.

The array chip AC is a chip capable of storing information. The array chip AC includes, for example, a stacked body LB, a plurality of memory pillars MP, a plurality of source lines SL, and a plurality of bit lines BL. The stacked body LB includes a plurality of word lines WL and a plurality of insulating layers IL. The plurality of word lines WL and the plurality of insulating layers IL are alternately stacked one by one in the Z direction. Although the plurality of source lines SL each extend in the X direction, the plurality of source lines SL are arranged at predetermined intervals in the Y direction. The plurality of bit lines BL each extend in the Y direction, but the plurality of bit lines BL are arranged at predetermined intervals in the X direction. The plurality of word lines WL each form a layer extending in the X direction and the Y direction, and are alternately stacked with the insulating layers IL to constitute the stacked body LB. The surrounding of the stacked body LB is also covered by an insulating layer.

The plurality of memory pillars MP penetrate the stacked body LB and extend in the Z direction. Each memory pillar MP includes an insulating portion, a channel layer, a tunnel insulating film, an electric charge accumulating portion, and a block insulating film from a center portion toward an outer periphery side of the memory pillar MP. One end portion of each of the memory pillars MP is connected to the source line SL. The other end portion of each memory pillar MP is connected to the bit line BL. A memory cell transistor MC is formed in an intersection portion of each memory pillar MP and each word line WL. The memory cell transistor MC is a storage element capable of storing information by accumulating electric charge.

The circuit chip CC includes a control circuit that controls the operation of the array chip AC. The circuit chip CC includes, for example, the semiconductor substrate 2, the plurality of transistors Tr, and a plurality of wires L. The plurality of transistor Tr1 are provided on the semiconductor substrate 2. An insulating layer covering each wire is formed on the semiconductor substrate 2. Each wire L connects the transistor Tr1 to the array chip AC via a contact formed on an upper surface of the insulating layer.

### 2. Configuration of Semiconductor Substrate and Transistor

Next, the configurations of the semiconductor substrate 2 and the transistor Tr1 will be described in detail.

### 2.1 Semiconductor Substrate

FIG. 2 is a cross-sectional view illustrating a configuration example of the semiconductor substrate 2 and the transistor Tr1.

As an example, the semiconductor substrate 2 is a silicon substrate including single crystal silicon. One or more element isolation regions formed from an insulator such as silicon oxide are provided in a part of an upper layer portion of the semiconductor substrate 2. The transistor Tr1 is provided in a region surrounded by the element isolation regions in the upper layer portion of the semiconductor substrate 2.

Note that the cross section illustrated in FIG. 2 only illustrates a region of the upper layer portion near the surface of the semiconductor substrate 2, and the element isolation regions are formed to a predetermined depth of the semiconductor substrate 2 from the surface of the semiconductor substrate 2 in a depth direction (−Z direction). In FIG. 2, illustration of the element isolation regions is omitted, and only the cross-sectional structure of the transistor Tr1 formed in the region surrounded by the element isolation regions is illustrated. In addition, in FIG. 2, illustration of the element isolation regions is omitted, and in FIG. 1 and FIG. 2, a main portion of the transistor Tr1 formed in an activation region in the region surrounded by the element isolation regions is illustrated.

### 2.2 Transistor

In the semiconductor device 1 illustrated in FIG. 1, as illustrated in the cross-sectional structure in FIG. 2, the transistor Tr1 is formed in a surface layer portion of the semiconductor substrate 2. The transistor Tr1 in this example is a field-effect transistor, and is, for example, a MOSFET (Metal-Oxide-Semiconductor-Field-Effect-Transistor).

The transistor Tr1 includes, for example, a gate electrode 10, the source region (first diffusion layer region) 11, the drain region (second diffusion layer region) 12, a gate insulating film 13, silicide layers 15 and 16, and insulating side walls 19. The transistor Tr1 includes a first base electrode (first base conductive region) 20 and a first contact electrode (first connection conductive region) 21 on the silicide layer 15. The transistor Tr1 includes a second base electrode (second base conductive region) 22 and a second contact electrode (second connection conductive region) 23 on the silicide layer 16.

The source region 11 is an example of the “first diffusion layer region.” The drain region 12 is an example of the “second diffusion layer region.” However, the drain region 12 may correspond to an example of the “first diffusion layer region”, and the source region 11 may correspond to an example of the “second diffusion layer region.”

The source region 11 and the drain region 12 are formed by means of ion implantation or the like from an upper surface portion of the semiconductor substrate 2 to a certain depth. The source region 11 and the drain region 12 are formed in regions that are insulated and isolated from the other regions in plan view in the aforementioned element isolation regions whose illustration is omitted. The source region 11 and the drain region 12 are arranged spaced apart from each other by a predetermined interval in the X direction as illustrated in FIG. 2. The source region 11 and the drain region 12 are formed spaced apart from each other in a surface direction (the X direction in FIG. 2) of an upper surface of the semiconductor substrate 2.

In this example, the silicide layer 15 is embedded in an upper layer portion of the source region (first diffusion layer region) 11. In this example, the silicide layer 16 is embedded in an upper layer portion of the drain region (second diffusion layer region) 12.

As illustrated in FIG. 2, the gate insulating film 13 is formed on the semiconductor substrate 2 above and between the upper part source region 11 and the drain region 12. The gate electrode 10 is arranged on the gate insulating film 13. The gate electrode 10 in this example has a rectangular or polygonal shape in plan view, the rectangular shape including a predetermined width in the X direction and a predetermined thickness (predetermined height) in the Z direction.

As illustrated in FIG. 2, the insulating side walls 19 are provided on both the left and right sides of the gate electrode 10 in the X direction, so as to sandwich the gate electrode 10 from the left and right. An extension portion 13A of the insulating film constituting the gate insulating film 13 is inserted between the gate electrode 10 and each of the insulating side walls 19. The gate insulating film 13 is formed into a concave shape as illustrated in a cross section in FIG. 2, together with a portion contacting the upper surface of the semiconductor substrate 2, and the extension portions 13A contacting side surfaces of the gate electrode 10. In addition, a high-dielectric constant material layer is between the gate insulating film 13 and the gate electrode 10. When providing the high-dielectric constant material layer, in the cross section illustrated in FIG. 2, the high-dielectric constant material layer may be arranged on the bottom surface side and side-surface sides of the gate electrode 10.

The silicide layer 15 is formed in the upper layer portion of the source region 11 more thinly than the source region 11. The silicide layer 15 includes, for example, a nickel platinum silicide layer (NiPtSi layer). The silicide layer 15 is formed by, for example, supplying a metal element, such as nickel (Ni), platinum (Pt), or cobalt (Co), to the source region 11, and thermally diffusing these metal elements to the semiconductor substrate side.

The silicide layer 16 is formed in the upper layer portion of the drain region 12 more thinly than the drain region 12. The silicide layer 16 includes a material equivalent to the material constituting the silicide layer 15.

In the structure illustrated in FIG. 2, an insulating layer 25 is provided around the insulating side walls 19 and on the semiconductor substrate 2. The first base electrode (first base conductive region) 20 surrounded by the insulating layer 25 is provided on the silicide layer 15. The first base electrode 20 is formed so as to be in close contact with an upper surface of the silicide layer 15. The thickness (height, e.g., in the Z direction) of the first base electrode 20 is lower or less than the thickness (height, e.g., in the Z direction) of the gate electrode 10. Accordingly, the side-surface sides and upper-surface side of the first base electrode 20 are covered with the insulating layer 25. Note that, in the example illustrated in FIG. 2, although the example is illustrated in which the insulating layer 25 is formed thicker than the first base electrode 20, the insulating layer 25 may be thinner than the first base electrode 20.

The second base electrode (second base conductive region) 22 surrounded by the insulating layer 25 is provided on the silicide layer 16. The second base electrode 22 is formed so as to be in close contact with an upper surface of the silicide layer 16. The thickness (height) of the second base electrode 22 is lower or less than the thickness (height) of the gate electrode 10. Accordingly, the side-surface sides and upper-surface side of the second base electrode 22 are covered with the insulating layer 25. Note that, in the example illustrated in FIG. 2, although the example is insulated in which the insulating layer 25 is formed thicker than the second base electrode 22, the insulating layer 25 may be thinner than the second base electrode 22.

The thickness (height) of the first base electrode 20 and the second base electrode 22 is equal to or lower than the thickness (height) of the gate electrode 10.

A covering layer 26 containing the metal element used in forming the silicide layer 15 is provided on the side-surface sides and upper-surface side of the first base electrode 20.

A covering layer 27 containing the metal element used in forming the silicide layer 16 is provided on the side-surface side and upper-surface side of the second base electrode 22.

In detail, the insulating layer 25 is formed so as to cover the covering layer 26 on the side-surface sides of the first base electrode 20 and the upper-surface side of the covering layer 26. In addition, the insulating layer 25 is formed so as to cover the covering layer 27 on the side-surface sides of the second base electrode 22 and the covering layer 27 on the upper-surface side.

As an example, the gate electrode 10 is made of a metal such as tungsten, but may be a semiconductor layer such as polysilicon, or may have a stacked structure of a semiconductor layers and a metal layer.

The insulating side walls 19 are formed of, for example, a silicon nitride film or a silicon oxide film. The insulating side walls 19 exist on the outer sides of the gate electrode 10 when viewed from the center of the transistor Tr1 (the center of gate electrode 10). When a high-dielectric constant material layer is provided between the gate electrode 10 and the insulating side walls 19, the insulating side walls 19 exist on the outer side of the high-dielectric constant material layer, and the insulating side walls 19 adhere to the high-dielectric constant material layer. In a region close to the source region 11, a bottom portion of the insulating side wall 19 covers a part of the source region 11. In a region close to the drain region, a bottom portion of the insulating side wall 19 covers a part of the drain region 12. Note that there is no particular limit to the height of the insulating side wall 19 in the Z direction. The insulating side walls 19 may be formed to have a height that covers a part or all of the side surfaces of the gate electrode 10.

The insulating layer 25 is made of a silicon nitride film or the like. The insulating layer 25 is provided so as to cover the transistor Tr1, the semiconductor substrate 2, and the like. In the form illustrated in FIG. 2, the insulating layer 25 located around the insulating side walls 19 is formed thicker than the insulating layer 25 covering the first base electrode 20 and the second base electrode 22. Projections 25A are formed in the insulating layer 25 that exists in a region close to the insulating side walls 19, and the portions of the projections 25A are formed to have the same thickness (height) as the insulating side walls 19.

An insulating layer 28 is stacked on the insulating layer 25. This insulating layer 28 covers an upper surface of the insulating layer 25 and is formed thicker than the insulating layer 25. The insulating layer 28 is formed so as to cover the insulating layer 25, and to also cover an upper surface of the gate electrode 10, upper surfaces of the extension portions 13A of the gate insulating film 13, and upper surfaces of the insulating side walls 19. The first contact electrode (first connection conductive region) 21 is formed on the first base electrode 20. The first contact electrode 21 penetrates an upper portion of the insulating layer 25 and the insulating layer 28 in the Z direction, and is electrically connected to the first base electrode 20. The second contact electrode (second connection conductive region) 23 is formed on the second base electrode 22. The second contact electrode 23 penetrates an upper portion of the insulating layer 25 and the insulating layer 28 in the Z direction, and is electrically connected to the second base electrode 22.

The insulating layer 28 is made of silicon oxide or the like.

A covering layer 30 made of a metal is provided on a side surface of the first contact electrode 21. The covering layer 30 contains a metal such as titanium nitride (TiN). The covering layer 30 covers the side surface of the first contact electrode 21. Note that the covering layer 30 may be constituted by the metal used in constituting the silicide layer 15.

A covering layer 31 made of a metal is provided on a side surface of the second contact electrode 23. The covering layer 31 contains a metal such as titanium nitride (TiN). The covering layer 31 covers the side surface of the second contact electrode 23. Note that the covering layer 31 may be constituted by the metal used in constituting the silicide layer 16.

### 2.2 Planar Layout According to Transistor of First Embodiment

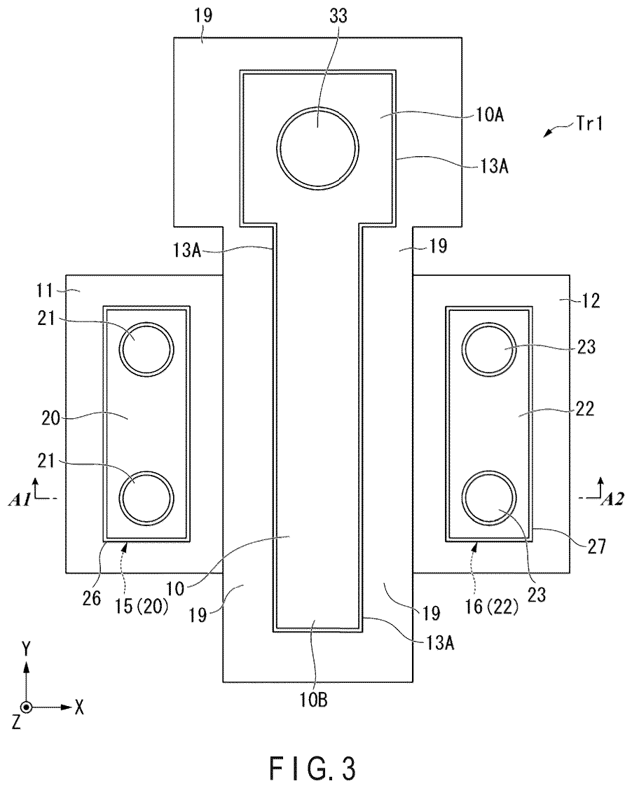

So far, although the cross-sectional structure of the transistor Tr1 has been described with reference to FIG. 2, FIG. 3 illustrates an example of the planar layout of the transistor Tr1.

As illustrated in FIG. 3, the transistor Tr1 in the first embodiment includes the silicide layer 15 and the first base electrode 20 that are connected to the source region 11 and that has rectangular shapes in plan view. The silicide layer 15 and the first base electrode 20 have the rectangular shapes with longer Y direction lengths than X direction lengths in plan view. The silicide layer 15 and the first base electrode 20 extend with their longitudinal directions being in the Y direction.

Two first contact electrodes 21, which are spaced apart from each other in a Y-axis direction, are connected to the first base electrode 20.

As illustrated in FIG. 3, the transistor Tr1 of the first embodiment includes the silicide layer 16 and the second base electrode 22 that are connected to the drain region 12 and have rectangular shapes in plan view. The silicide layer 16 and the second base electrode 22 have rectangular shapes in plan view with longer Y direction lengths than X direction lengths. The silicide layer 16 and the second base electrode 22 extend with their longitudinal directions being in the Y direction.

Two second contact electrodes 23, which are spaced apart from each other in the Y-axis direction, are connected to the second base electrode 22.

As illustrated in FIG. 3, the transistor Tr1 includes the gate electrode 10 sandwiched between the source region 11 and the drain region 12 in plan view. The gate electrode 10 in this example has a rectangular or polygonal shape in plan view, e.g., that is longer in the Y direction than in the X direction. One end side of the gate electrode 10 in the Y direction in plan view passes through a region between the source region 11 and the drain region 12, and extends slightly outside the region. For example, the portion of the gate electrode 10 passing through the region between the source region 11 and the drain region 12 has the rectangular shape. In addition, on the extending end side, a connecting portion 10A having a square shape in plan view with a larger X-direction width than that of the gate electrode 10 is formed. As described earlier, the insulating side walls 19 are provided on both sides of the gate electrode 10 in the X direction that is provided between the source region 11 and the drain region 12. According to the plan view layout illustrated in FIG. 3, these insulating side walls 19 extend so as to surround the connecting portion 10A in the gate electrode 10.

The other end side of the gate electrode 10 in the Y direction in plan view includes an extension portion 10B that passes through the region between the source region 11 and the drain region 12, and extends slightly outside the region. The aforementioned insulating side walls 19 are formed so as to surround the extension portion 10B in the gate electrode 10 in plan view.

A third contact electrode 33 extending in the Z direction is connected to the connecting portion 10A of the gate electrode 10. Since the cross section along a line A1-A2 illustrated in FIG. 3 corresponds to FIG. 2, the third contact electrode 33 is not shown in FIG. 2.

The transistor Tr1 configured as described above can adjust the amount of electric current that flows between the drain region 12 and the source region 11, with the level of the voltage applied to gate electrode 10 from the third contact electrode 33. In the transistor Tr having the structure illustrated in FIG. 3, in order to increase the areas of the silicide layers 15 and 16, the silicide layers 15 and 16 having the rectangular shapes in plan view are employed.

Making the silicide layer 15 have the rectangular shape in plan view contributes to reduction of the contact resistance and sheet resistance between the silicide layer 15 and the source region 11, and the contact resistance and sheet resistance between the silicide layer 15 and the first base electrode 20. In addition, making the silicide layer 16 have the rectangular shape in plan view contributes to reduction of the contact resistance and sheet resistance between the silicide layer 16 and the drain region 12, and the contact resistance and sheet resistance between the silicide layer 16 and the second base electrode 22.

However, on the other hand, the increase in the parasitic capacitance described below becomes a problem.

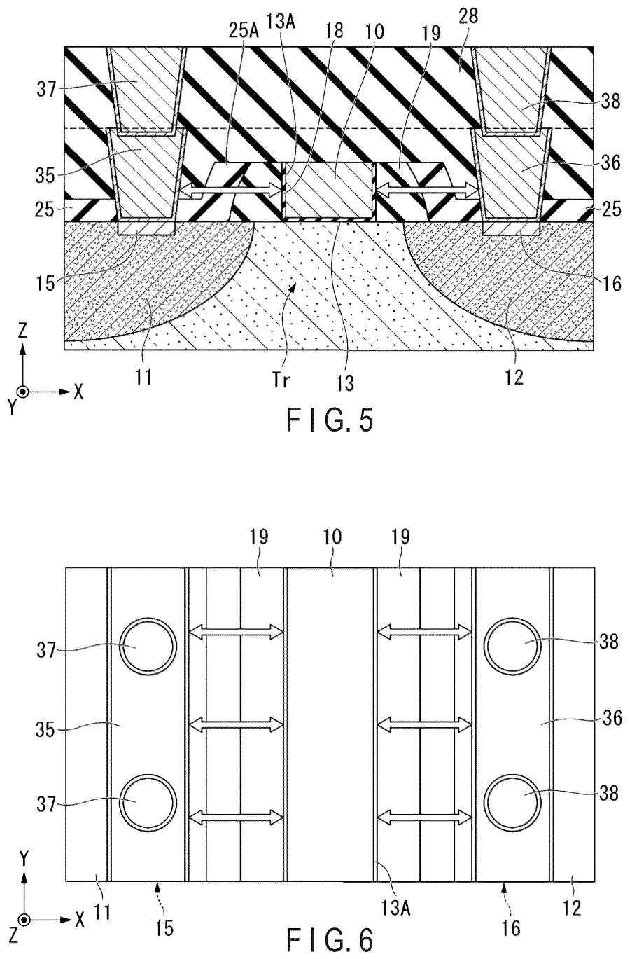

For example, FIG. 5 illustrates a structure in which the silicide layer 15 is formed in the upper layer portion of the source region 11, and the silicide layer 16 is formed in the upper layer portion of the drain region 12 in a cross-sectional structure of a transistor Tr of a comparative example.

In the transistor Tr of the comparative example, when forming the silicide layer 15 into a rectangular shape in plan view as illustrated in FIG. 6, a tall first base electrode 35 is formed on the silicide layer 15. In addition, when forming the silicide layer 16 into a rectangular shape in plan view, a tall second base electrode 36 is formed on the silicide layer 16.

The tall first base electrode 35 is an electrode taller than the height of the gate electrode 10. The tall second base electrode 36 is an electrode taller than the height of the gate electrode 10.

In the structure of the comparative-example, a first contact electrode 37 is formed on the first base electrode 35, and a second contact electrode 38 is formed on the second base electrode 36.

In the transistor Tr of the comparative example illustrated in FIG. 5 and FIG. 6, the first base electrode 35 and the second base electrode 36 taller than the gate electrode 10 are arranged at left and right positions close to the gate electrode 10. Therefore, although the transistor Tr having the structure of the comparative example has an advantage due to low sheet resistance and contact resistance, there is a problem that the parasitic capacitance between the gate electrode 10 and the first base electrode 35 and the parasitic capacitance between the gate electrode 10 and the second base electrode 36 become large.

In FIG. 5 and FIG. 6, the parasitic capacitance becoming large due to the close arrangement of the gate electrode 10 and the first base electrode 35 is indicated in a highlighted manner by arrows. In FIG. 5 and FIG. 6, the parasitic capacitance becoming large due to the close arrangement of the gate electrode 10 and the second base electrode 36 is indicated in a highlighted manner by arrows.

On the other hand, in the transistor Tr1 in the first embodiment described earlier, as illustrated in FIG. 2, the first base electrode 20 and the second base electrode 22 shorter (lower) than the gate electrode 10 are arranged on both sides of the gate electrode 10. Therefore, compared with the transistor Tr having the structure in the comparative example, the transistor Tr1 in the first embodiment can reduce the parasitic capacitance that is likely to occur between the gate electrode 10 and the first base electrode 20. In addition, the parasitic capacitance that is likely to occur between the gate electrode 10 and the second base electrode 22 can be reduced.

In the transistor Tr1 in the first embodiment illustrated in FIG. 2 and FIG. 3, the sheet resistance and the contact resistance can be made low by providing the silicide layers 15 and 16, and the parasitic capacitance can also be suppressed more than the structure in the comparative example.

Note that the effect of suppressing the parasitic capacitance can also be similarly obtained when the height of the gate electrode 10 and the height of the first base electrode 20 are made equivalent, and when the height of the gate electrode 10 and the height of the second base electrode 22 are made equivalent.

### 2.3 Planar layout of Transistor According to Second Embodiment

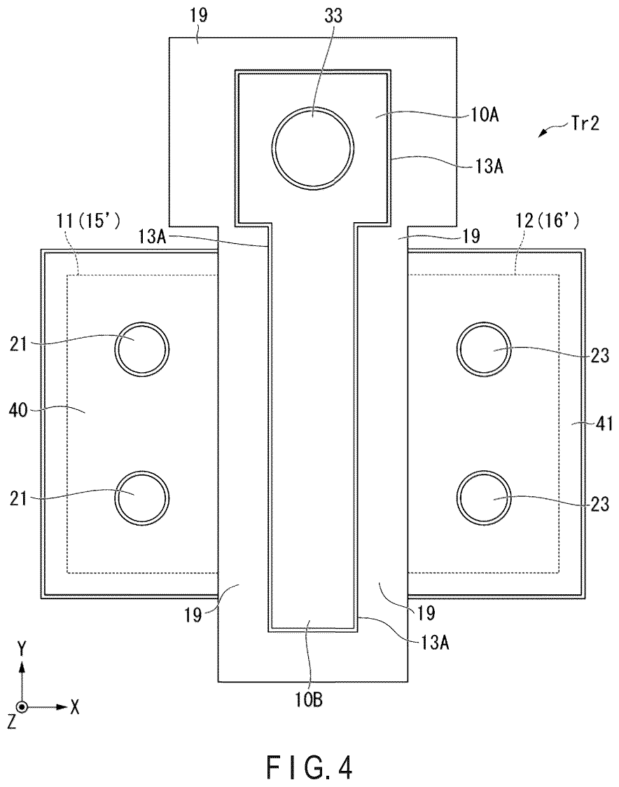

FIG. 4 illustrates an example of the planar layout according to a transistor Tr2 in a second embodiment.

In the transistor Tr2 in the second embodiment, the same numerals are given to components equivalent to those of the transistor Tr1 in the first embodiment, and a description will be omitted for common components.

In the transistor Tr2, a silicide layer 15′ having a size that almost covers the source region 11 in plan view is provided. A first base electrode (first base conductive region) 40, which is larger than this silicide layer 15′ both in the X direction and the Y direction in plan view, is provided. In addition, a silicide layer 16′ having a size that almost covers the drain region 12 is provided. A second base electrode 41 (second base conductive region), which is larger than this silicide layer 16′ both in the X direction and the Y direction in plan view, is provided.

The first contact electrode 21 is formed on the first base electrode 40, which is similar to the configuration of the aforementioned first embodiment. The second contact electrode 23 is formed on the second base electrode 41, which is similar to the configuration of the aforementioned first embodiment.

The other structures are equivalent to those of the transistor Tr1 in the first embodiment.

According to the structure of second embodiment, since the silicide layers 15′ and 16′ having larger areas in plan view compared with the structure of the first embodiment are provided, the sheet resistance can be made lower. As for capability of reducing the parasitic capacitance, the transistor Tr2 in the second embodiment can also obtain an effect equivalent to those of the transistor Tr1 in the first embodiment.

In addition, according to the structure of the second embodiment, by implementing a manufacturing method that will be described later, it is possible to employ a structure that is capable of preventing an end portion from falling in a border region with the element isolation region as will be described later. The details of this structure will be described later.

### Manufacturing Method

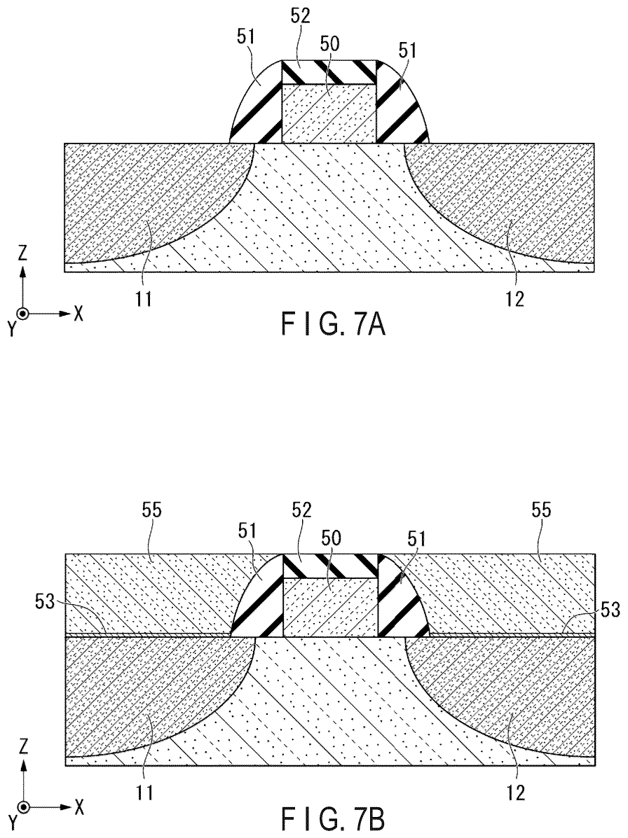

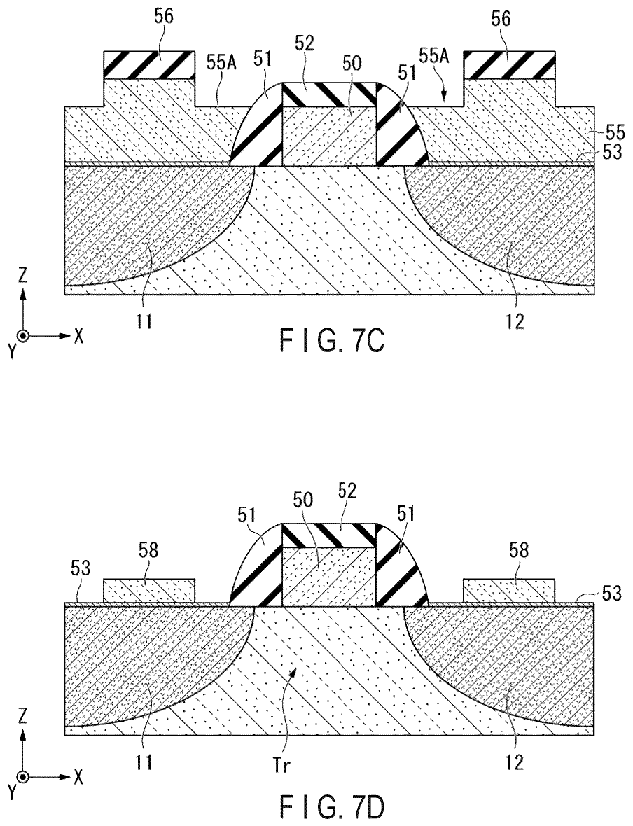

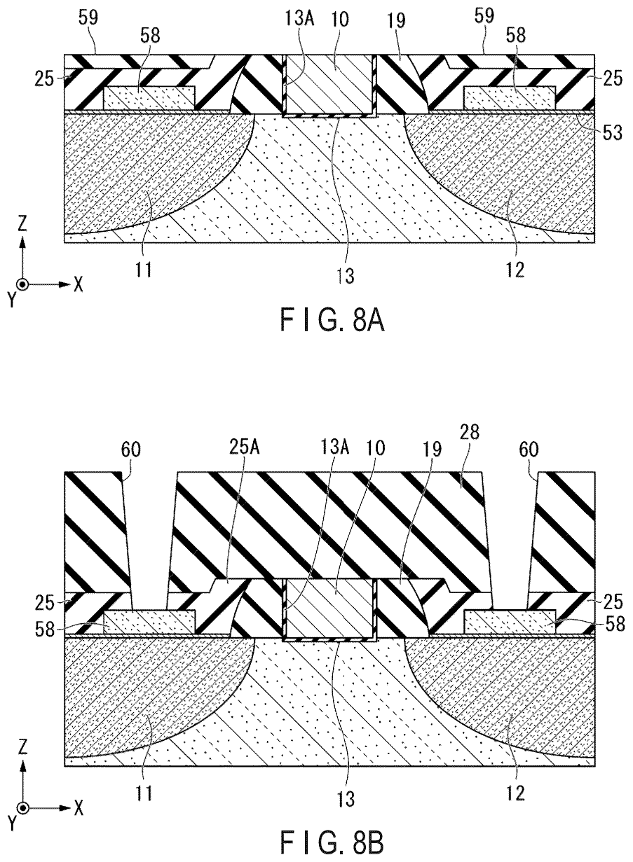

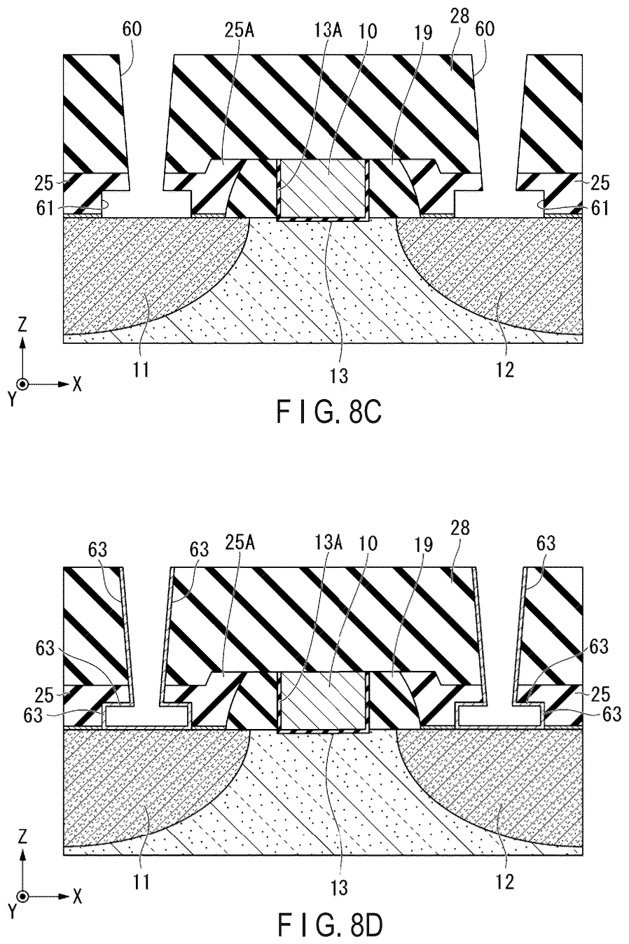

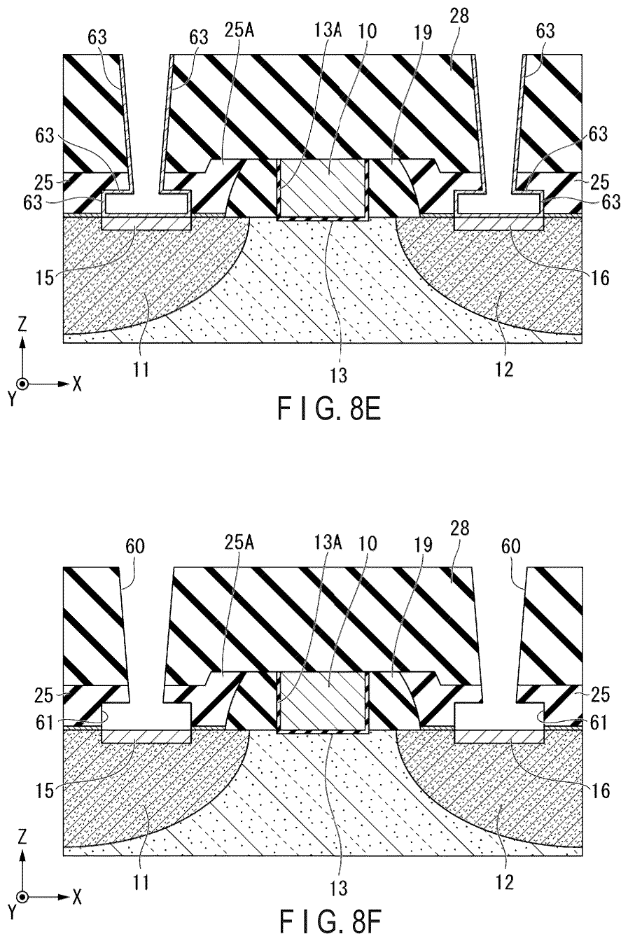

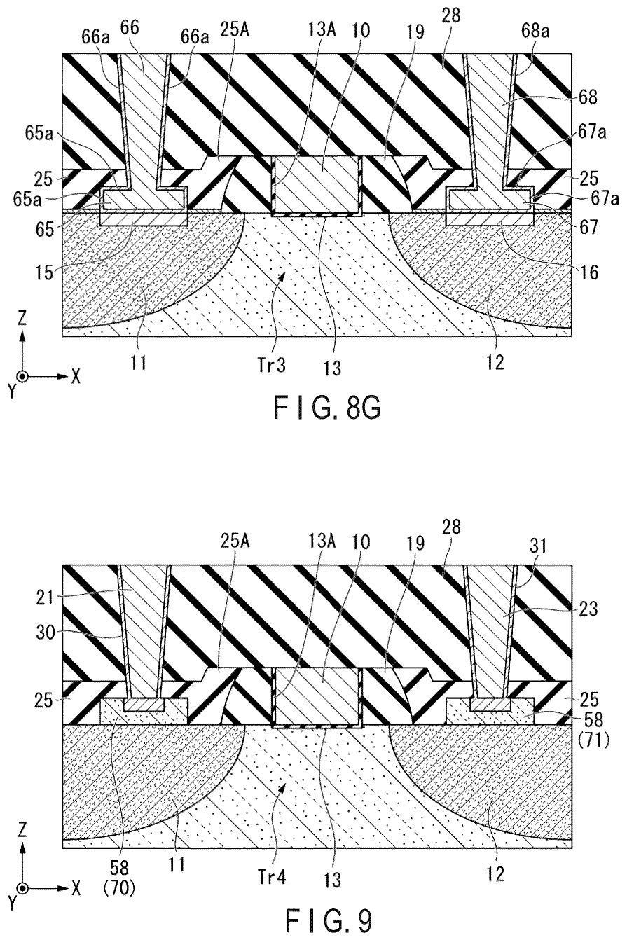

FIG. 7A to FIG. 7D and FIG. 8A to FIG. 8D are explanatory diagrams illustrating an example of steps of manufacturing the transistor Tr1 having the cross-sectional structure illustrated in FIG. 2.

As illustrated in FIG. 7A, a dummy gate film 50 having the same shape as a gate electrode is formed in a region for forming the gate electrode on the upper surface of the semiconductor substrate 2, and insulating side walls 51 and an insulation cover 52 are formed so as to cover side surfaces and an upper surface of the dummy gate film 50 in correspondence with the regions in which the insulating side walls 19 are to be formed. A polysilicon film can be used for the dummy gate film 50. A silicon nitride film or a silicon oxide film can be used for the insulating side walls 51 and the insulation cover 52.

Thereafter, ion implantation is performed to form the source region 11 and the drain region 12 on the upper surface side of the semiconductor substrate 2.

Next, as illustrated in FIG. 7B, the upper surface of the semiconductor substrate 2 is oxidized to form an upper surface oxide film 53. The upper surface oxide film 53 is formed as a chemical oxide film utilizing ozone water or the like. This surface oxide film 53 is thinly formed on the upper surface of the semiconductor substrate 2 and around the insulating side walls 51. Thereafter, a covering layer 55 made of amorphous silicon or the like is formed so as to cover the upper surface oxide film 53, the insulating side walls 51, and the insulation cover 52. Next, an upper surface of the covering layer 55 is polished and flattened by using a grinding method such as chemical machinery polishing (CMP), and an upper surface of the insulation cover 52 is exposed as illustrated in FIG. 7B.

Next, as illustrated in FIG. 7C, a resist layer 56 is formed on the covering layer 55 on both sides of the insulating side walls 51 and 51 in the X direction. Next, a photolithography step is performed to form recess portions 55A on both sides of the insulating side walls 51 and 51 in the X direction. The regions in which the resist layer 56 is to be formed correspond to the regions in which the silicide layers 15 and 16 are formed in plan view in the structure illustrated in FIG. 3.

When etching the covering layer 55 in the photolithography step, etching is adjusted so as to remove a part of the thickness of the covering layer 55. In addition, the recess portions 55A have a depth that exposes upper portions of the insulating side walls 51 and the insulation cover 52 in the recess portion 55A. Accordingly, the recess portions 55A are formed as illustrated in FIG. 7C.

The resist layer 56 is removed from the state illustrated in FIG. 7C, and the entire surface of the covering layer 55 is etched. Then, as illustrated in FIG. 7D, a part of the covering layer 55 remains as a residual layer 58 so as to correspond to the positions at which the resist layer 56 is formed. As a result of etching in the entire surface, the upper surface oxide film 53 is exposed in regions around the residual layer 58.

Next, the insulating layer 25 and the insulating layer 59 are formed so as to cover the insulating side walls 51 and 51, the insulation cover 52, the residual layer 58, and the like, the upper portions of insulating side walls 51 and 51 and the insulation cover 52 are removed by using a grinding method such as chemical machinery polishing to expose the dummy gate film 50, and thereafter, the dummy gate film 50 is removed by selective removal that uses alkaline solution (choline solution or the like). Since a recess portion is generated between the insulating side walls 51 and 51, when the gate insulating film 13 and the gate electrode 10 are formed in this recess portion, the state illustrated in FIG. 8A is obtained. When forming a high-dielectric constant material layer on the gate insulating film 13, the gate electrode 10 is formed after forming the high-dielectric constant material layer.

Next, the insulating layer 28 covering the entire surface is formed, and contact holes 60 that reach the residual layer 58 are formed by using a methods such as dry etching. In the case of the structure illustrated in FIG. 3, the positions at which the contact holes 60 are formed are the positions at which the first contact electrode 21 and the second contact electrode 23 are to be formed.

Next, an etching solution such as choline solution or hydrofluoric acid is used to remove the residual layer 58 and the upper surface oxide film 53 under the residual layer 58 via the contact holes 60 as illustrated in FIG. 8C. Accordingly, cavities 61 are formed in the portions from which the residual layer 58 and the upper surface oxide film 53 are removed, and the contact holes 60 are connected to the cavities 61. When the structure illustrated in FIG. 8C is obtained, deposition of a metal element for forming silicide layers is performed via the contact holes 60. As a metal for forming the silicide layers, any metal such as Ni, (NiPt), Co, or titanium can be used.

With the above processing, as illustrated in FIG. 8D, a covering layer 63 of the metal element is formed inside the contact holes 60 and inside cavities 61.

Thereafter, heat treatment for forming the silicide layers is performed to perform diffusion of the metal element for forming the silicide layers. With this heat treatment, the metal element is caused to react with Si, and as illustrated in FIG. 8E, the silicide layer 15 is generated by diffusing and reacting the metal element in the upper layer portion of the source region 11, and the silicide layer 16 is generated by diffusing and reacting the metal element in the upper layer portion of the drain region.

Next, the covering layer 63 remaining in the contact holes 60 and the cavities 61 is removed with etching solution, so as to obtain a state in which there is no deposit on inner surfaces of the contact holes 60 and the cavities 61 as illustrated in FIG. 8F. Thereafter, a film of titanium nitride or the like as a barrier metal is formed on the inner surfaces of the contact holes 60 and the cavities 61. With this film formation processing, a covering layer 65a is formed on the inner surfaces of the cavities 61 on the silicide layer 15, and a covering layer 66a is formed on the inner surfaces of the contact holes 60 on the cavities 61. In addition, a covering layer 67a is formed on the inner surfaces of the cavities 61 on the silicide layer 16, and a covering layer 68a is formed on the inner surfaces of the contact hole 60 on the cavities 61.

Next, the first base electrode (first base conductive region) 65 and the first contact electrode (first connection conductive region) 66 are formed on the silicide layer 15. The second base electrode (second base conductive region) 67 and the second contact electrode (second connection conductive region) 68 are formed on the silicide layer 16.

With the steps above, it is possible to obtain a transistor Tr3 having a cross-sectional structure illustrated in FIG. 8G equivalent to the cross-sectional structure illustrated in FIG. 2.

### Third Embodiment

FIG. 9 illustrates a cross-sectional structure of a transistor Tr4 according to a third embodiment.

In the transistor Tr1 in the first embodiment, the silicide layer 15 is formed in the upper layer portion of the source region 11, and the silicide layer 16 is formed in the upper layer portion of the drain region 12. In addition, in the manufacturing method thereof, the residual layer 58 is removed from the state illustrated in FIG. 8B, and the silicide layer 15 and the first base electrode 65 as well as the silicide layer 16 and the second base electrode 67 are formed.

Here, it is also possible to constitute the first base electrode based on the residual layer 58 while leaving the residual layer 58, by performing ion implantation by using polysilicon as the material that constitutes the residual layer 58, without removing residual layer 58 on the source region 11. In addition, it is also possible to constitute the second base electrode based on the residual layer 58, by performing ion implantation by using polysilicon as the material that constitutes the residual layer 58, without removing the residual layer 58 on the drain region 12.

The cross-sectional structure illustrated in FIG. 9 illustrates the transistor Tr4 in the third embodiment in which a first base electrode 70 based on the residual layer 58 is formed on the source region 11, and a second base electrode 71 based on the residual layer 58 is formed on the drain region 12.

In the transistor Tr4 having the structure illustrated in FIG. 9, it is possible to realize a transistor structure in which the first base electrode 70 and the second base electrode 71 are formed as pseudo diffusion regions, junction leakage with the source region 11 can be reduced, junction leakage with the drain region 12 can be reduced, and short channel effects can be improved.

### Fourth Embodiment

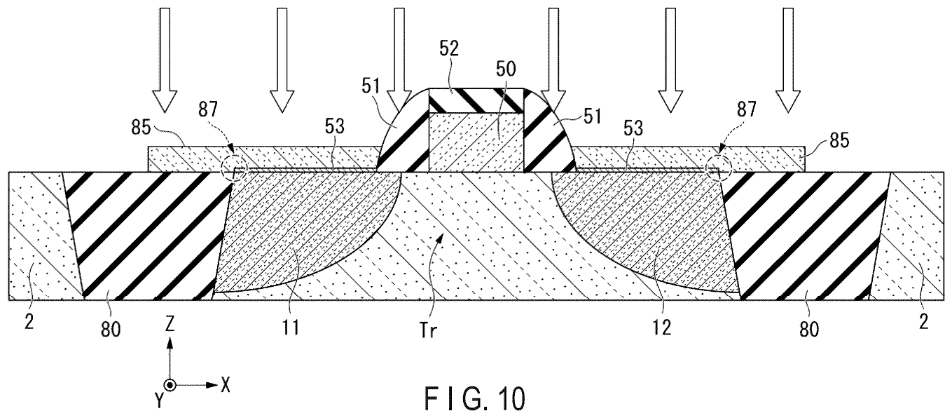

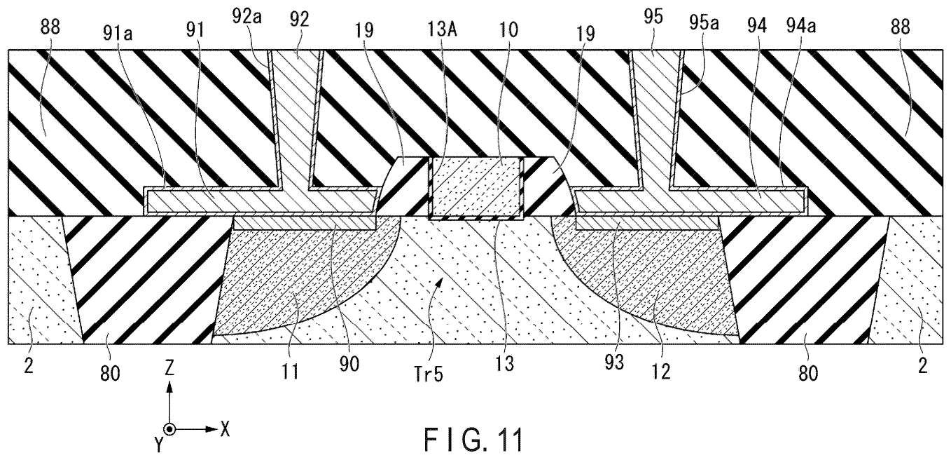

FIG. 10 and FIG. 11 are explanatory diagrams illustrating an example of a method of manufacturing the transistor Tr2 having the planar layout illustrated in FIG. 4.

In FIG. 10, element isolation regions 80 and 80 that define activation regions of the semiconductor substrate 2 are illustrated spaced apart from each other on both sides along the X direction, and a description will be given below of a method of forming a transistor Tr5 having the configuration illustrated in FIG. 11 between the element isolation regions 80 and 80.

The source region 11 and the drain region 12 are formed spaced apart from each other in the X direction by being sandwiched by the element isolation regions 80 and 80 in the upper layer portion of the semiconductor substrate 2.

The insulating side walls 51 and 51 similar to the structure illustrated in FIG. 7A are formed on the region between the source region 11 and the drain region 12, the dummy gate film 50 is formed between the insulating side walls 51 and 51, and the insulation cover 52 is formed on the dummy gate film 50. In addition, the upper surface oxide film 53 is formed on the surface of the semiconductor substrate 2 around the insulating side walls 51 and 51.

FIG. 10 illustrates a state in which a covering layer 85 covering the surface of the semiconductor substrate 2 and the element isolation regions 80 up to their centers in the width direction is formed on both sides of the insulating side walls 51 and 51 in the X direction. The state illustrated in FIG. 10 corresponds to a state close to FIG. 7D, which has been described above for the method of manufacturing a transistor.

Although illustration of the element isolation regions 80 is omitted in the manufacturing method illustrated in FIG. 7A to FIG. 8D, FIG. 10 draws up to the element isolation regions 80. In addition, it is illustrated that an end portion of the upper surface oxide film 53 on the element isolation region 80 side extends to the boundary with the element isolation region 80. In addition, it is illustrated that an end portion of the covering layer 85 on the element isolation region 80 side reaches the element isolation region 80.

The covering layer 85 can be formed from amorphous silicon. It is assumed that the thickness of the covering layer 85 is enough to cover the bottom portion side of the insulating side walls 51.

Thereafter, when an insulating layer is formed on the semiconductor substrate 2 as in the steps illustrated in FIG. 8A, FIG. 8B, FIG. 8C and FIG. 8D, the covering layer 85 under the insulating layer is removed to form cavities, and filling and diffusion of an element for forming silicide layers, formation of the first base electrode layer and the second base electrode layer, and formation of the first contact electrode and the second contact electrode are performed in the cavities, the structure illustrated in FIG. 11 is obtained.

In the structure illustrated in FIG. 11, an insulating layer 88 is formed on the semiconductor substrate 2, a silicide layer 90 is formed in a surface layer portion of the source region 11, and a first base electrode 91 and a first contact electrode 92 are formed on the silicide layer 90. A silicide layer 93 is formed in a surface layer portion of the drain region 12, and a second base electrode 94 and a second contact electrode 95 are formed on the silicide layer 93.

A covering layer 91a containing an element for forming the silicide layer 90 is formed on a bottom surface, side surfaces, and an upper surface of the first base electrode 91, and a covering layer 92a containing an element for forming the silicide layer 90 is formed on a side surface of the first contact electrode 92. A covering layer 94a containing an element for forming the silicide layer 93 is formed on a bottom surface, side surfaces, and an upper surface of the second base electrode 94, and a covering layer 95a containing an element for forming the silicide layer 93 is formed on a side surface of the second contact electrode 95.

When manufacturing the structure illustrated in FIG. 11, as illustrated in FIG. 10, the upper surface oxide film 53 reaches to the edge of the element isolation region 80, and the covering layer 85 is formed thereon. In this state, when processing upper end portions of the insulating side walls 51 and the insulation cover 52 by ion etching, since the end portions of the element isolation regions 80 are protected, damage or the like does not occur in an adjacent source region end and an adjacent drain region end.

If recess portions are generated in the end portions of the element isolation regions 80 by etching or the like, and damage occurs in the source region end or the drain area end, this causes a junction leakage current to occur.

Here, in ion etching illustrated in FIG. 10, since the boundary portion (the portion surrounded by a circle indicated by a numeral 87 in FIG. 10) between the source region 11 and the element isolation region 80 is protected, no damage occurs in the source region end. In addition, in the ion etching, since the boundary portion between the drain region 12 and the element isolation region 80 is protected, no damage occurs in the drain area end.

Note that, in the first embodiment, both the first base electrode 20 and the second base electrode 22 formed on both sides of the gate electrode 10 in the X direction are formed thinner than the gate electrode 10. However, the problem in the embodiments can be solved by forming at least one of the first base electrode 20 and the second base electrode 22 thinner than the gate electrode 10. Similarly, the problem in the embodiments can be solved by forming at least one of the first base electrode 40 and the second base electrode 41 in the second embodiment thinner than the gate electrode 10. Similarly, the problem in the embodiments can be solved by forming at least one of the first base electrode 70 and the second base electrode 71 in the third embodiment thinner than the gate electrode 10.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. The accompanying claims and their equivalents are intended to cover such forms or modification as would fall within the scope and spirit of the inventions.

What is claimed is

1. A semiconductor device, comprising:
a semiconductor substrate;
a first diffusion layer region and a second diffusion layer region on the semiconductor substrate and spaced apart from each other in a surface direction of the semiconductor substrate;
a gate insulating film on the semiconductor substrate, at least a part of the gate insulating film being in a region between the first diffusion layer region and the second diffusion layer region;
a gate electrode on an opposite side of the gate insulating film from the semiconductor substrate;
a first base conductive region on an opposite side of the first diffusion layer region from the semiconductor substrate, the first base conductive region extending in the surface direction of the semiconductor substrate;
a first connection conductive region connected to the first base conductive region;
a second base conductive region on an opposite side of the second diffusion layer region from the semiconductor substrate, the second base conductive region extending in the surface direction of the semiconductor substrate; and
a second connection conductive region connected to the second base conductive region,
wherein a height of at least one of the first base conductive region and the second base conductive region is equal to or less than a height of the gate electrode.

2. The semiconductor device of claim 1, wherein a silicide layer is between the first diffusion layer region and the first base conductive region or between the second diffusion layer region and the second base conductive region.

3. The semiconductor device of claim 1, wherein the gate electrode contains a metal or polysilicon.

4. The semiconductor device of claim 1, wherein at least one of the first base conductive region and the second base conductive region has a rectangular shape in plan view.

5. The semiconductor device of claim 1, wherein:
the gate electrode has a rectangular shape in plan view, and
at least one of the first base conductive region and the second base conductive region has a rectangular shape along a longitudinal direction of the gate electrode having the rectangular shape in plan view.

6. The semiconductor device of claim 1, wherein:
the first base conductive region and the second base conductive region are base electrodes that penetrate an insulating layer on the semiconductor substrate in a thickness direction of the insulating layer, and
the first connection conductive region and the second connection conductive region are contact electrodes that penetrate the insulating layer on the semiconductor substrate in the thickness direction.

7. The semiconductor device of claim 1, wherein the height of the at least one of the first base conductive region and the second base conductive region is less than the height of the gate electrode.

8. The semiconductor device of claim 1, wherein the height of the at least one of the first base conductive region and the second base conductive region is equal to the height of the gate electrode.

9. The semiconductor device of claim 1, wherein:
a portion of the gate electrode that is between the first diffusion layer region and the second diffusion layer region in the surface direction of the semiconductor substrate has a rectangular shape in plan view, and
at least one of the first base conductive region and the second base conductive region has a rectangular shape along a longitudinal direction of the portion of the gate electrode having the rectangular shape in plan view.

10. The semiconductor device of claim 1, further comprising insulating side walls on sides of the gate electrode, wherein the insulating side walls are between a side of the gate electrode and the first base conductive region and between another side of the gate electrode and the second base conductive region.

11. The semiconductor device of claim 1, wherein:
a first silicide layer is between the first diffusion layer region and the first base conductive region,
a second silicide layer is between the second diffusion layer region and the second base conductive region, and
each of the first silicide layer and the second silicide layer has a rectangular shape in plan view.
